(19) United States
(12) Patent Application Publication
(10) Pub. No.: US 2019/0242818 A1
(43) Pub. Date: Aug. 8, 2019

(54) ABSORBANCE METER AND SEMICONDUCTOR MANUFACTURING DEVICE USING ABSORBANCE METER

(71) Applicant: HORIBA STEC, CO., LTD., Kyoto (JP)

(72) Inventors: Hiroshi NISHIZATO, Kyoto (JP); Masakazu MINAMI, Kyoto (JP); Yuhei SAKAGUCHI, Kyoto (JP)

(73) Assignee: HORIBA STEC, CO., LTD., Kyoto (JP)

(21) Appl. No.: 16/333,265

(22) PCT Filed: Sep. 14, 2017
(86) PCT No.: PCT/JP2017/033238

§ 371 Date: Mar. 14, 2019

(30) Foreign Application Priority Data
Sep. 15, 2016 (JP) 2016-180885

(51) Int. Cl. G01N 21/61; G01N 1/38; H01L 21/67; C23C 16/52

(52) U.S. Cl. CPC G01N 21/61; C23C 16/52; H01L 21/67253; G01N 1/38

(57) ABSTRACT

Obtained is an absorbance meter capable of, when measuring high-temperature sample gas, without increasing the distance from a light source part to a light receiving part, protecting the light source part and the light receiving part from the heat of the sample gas and keeping measurement accuracy high. A sample accommodation part including an accommodation space for accommodating the sample gas, the light source part for radiating light into the accommodation space, the light receiving part for receiving light exiting from inside the accommodation space, a first insulation part disposed adjacent to the light source part side of the sample accommodation part, a second insulation part disposed adjacent to the light receiving part side of the sample accommodation part, a first cooling part disposed adjacent to the first insulation part, and a second cooling part disposed adjacent to the second insulation part are provided.

### TECHNICAL FIELD

The present invention relates to an absorbance meter and a semiconductor manufacturing device using the absorbance meter.

### BACKGROUND ART

As an absorbance meter using an infrared spectroscopy (IR) for measuring the concentration of sample gas, as disclosed in Patent Literature 1, there is one having: a sample accommodation part provided with a pair of translucent windows oppositely provided sandwiching an accommodation space for accommodating the sample gas; a light source part for radiating light into the accommodation space through a translucent window on one side; a light receiving part for receiving light passing through the accommodation space and existing from a translucent window on the other side; and insulation parts disposed adjacent to the light source part side and light receiving part side of the sample accommodation part and having through-holes facing the opposite translucent windows.

In the above-described conventional absorbance meter, even when measuring the sample gas at high temperature, the heat of the sample gas is blocked at the insulation parts, and therefore less likely to be transferred to the light source part and the light receiving part, and this can prevent the light source part and the light receiving part from being damaged by the heat of the sample gas.

Meanwhile, the above-described conventional absorbance meter is also used in a bubbling type semiconductor manufacturing device, and in recent years, as a material serving as a source for material gas to be carried by the bubbling type semiconductor manufacturing device, a low vapor pressure material whose vaporization rate is low as compared with conventional materials and from which the amount of the material gas obtainable at the time of vaporization is very small has been used. In addition, when manufacturing a semiconductor from the material gas produced by vaporizing such a low vapor pressure material, in order to keep the concentration of the material gas as high as possible, the material is heated to the highest possible temperature at which the material is not decomposed, and therefore the temperature of the sample gas to be introduced into the absorbance meter may be raised to 300° C. or more.

When trying to use the above-described conventional absorbance meter to measure such high temperature sample gas whose temperature is raised as high as 300° C. or more, it is necessary to considerably increase the thicknesses of the insulation parts in order to protect the light source part and the light receiving part from the heat of the sample gas, and along with this, the distance from the light source part to the light receiving part is also increased, so this causes the intensity of light received by the light receiving part to be reduced, thus reducing measurement accuracy.

### CITATION LIST

### Patent Literature

[Patent Literature 1]

Japanese Unexamined Patent Application Publication No. 2007-101433

### SUMMARY OF THE INVENTION

### Technical Problem

Therefore, the main object of the present invention is to obtain an absorbance meter capable of, when measuring high-temperature sample gas, without increasing the distance from a light source part to a light receiving part, protecting the light source part and the light receiving part from the heat of the sample gas and keeping measurement accuracy high.

### Solution to Problem

That is, the absorbance meter according to the present invention is one including: a sample accommodation part provided with a pair of translucent windows oppositely attached sandwiching an accommodation space for accommodating sample gas; a light source part for radiating light into the accommodation space through a translucent window on one side; and a light receiving part for receiving light passing through the accommodation space and exiting from a translucent window on the other side, and further includes: an insulation part interposed between the sample accommodation part and any one or both of the light source part and the light receiving part; and a cooling part interposed between the sample accommodation part and the light source part or the light receiving part, as with the at least one insulation part, in which the insulation part is arranged on a sample accommodation part side with respect to the cooling part.

In addition, the insulation part in the present invention is one adapted to block the heat of the sample gas transferred via the sample accommodation part to some extent from being transferred to the light source part or the light receiving part, and formed of a material having low heat transfer coefficient as compared with a material forming the sample accommodation part. In contrast to this, the cooling part in the present invention is one adapted to perform cooling before the heat of the sample gas transferred to the cooling part via the sample accommodation part is transferred to the light source part or the light receiving part, and includes, for example, one adapted to perform cooling by reducing the temperature of the cooling part itself, one adapted to perform cooling by improving the heat dissipation efficiency of the cooling part itself, or the combination of them. That is, the cooling part in the present invention only has to be one adapted to facilitate a reduction in the temperature of heat so as to prevent the heat transferred to the cooling part via the sample accommodation part from being transferred to the light source part or the light receiving part, and specifically one adapted to keep the temperature of a surface opposite to at least the light source part side or the light receiving part side at the temperature of the light source part or light receiving part or less.

In such a configuration, since the heat of the sample gas transferred from the sample accommodation part is forcibly cooled by the cooling part, even when decreasing the thickness of the insulation part, the light source part or the light receiving part can be prevented from being damaged by the heat of the sample gas at high temperature (e.g., 300° C. or more), and along with this, the distance from the light source part to the light receiving part can be shortened, thus making it possible to keep measurement accuracy high. Also, since the insulation part is interposed between the translucent window disposed on the sample accommodation part and the cooing part, the outer surface of the translucent window (the surface on the side opposite to the surface on the accommodation space side) is not directly cooled by the cooling part, and this prevents the occurrence of a large temperature difference between the inside and outside of the translucent window to make it difficult for dew condensation to occur on the inner surface of the translucent window (the surface on the accommodation space side), making it possible to keep the measurement accuracy high. Incidentally, when dew condensation occurs on the translucent window, the dew condensation blocks light to reduce the intensity of the light, thus reducing the measurement accuracy.

The absorbance meter is preferably one in which at least one set of parts that are selected from the sample accommodation part, the light source part, the light receiving part, the insulation part interposed between the sample accommodation part and the light source part, the cooling part interposed between the sample accommodation part and the light source part as with the insulation part, the insulation part interposed between the sample accommodation part and the light receiving part, and the cooling part interposed between the sample accommodation part and the light receiving part as with the insulation part and mutually oppositely arranged is such that the parts are adjacent with opposite surfaces thereof in close contact, and further preferably one in which all sets of parts are such that the parts are adjacent with opposite surfaces thereof in close contact. As the number of sets of adjacent parts is increased, the distance from the light source part to the light receiving part is shortened, thus increasing the measurement accuracy.

In addition, at least one of the translucent windows may be attached to the sample accommodation part via a fixation frame, and the fixation frame may be formed of a metal material. In a conventional absorbance meter, as a seal for attaching a translucent window to a sample accommodation part, one made of rubber having low thermal conductivity has been used, and heat transferred from the sample accommodation part has been blocked by the seal made of the rubber and prevented from being efficiently transferred to the translucent window, so that this has prevented a rise in the temperature of the translucent window to cause a large temperature difference between the translucent window and sample gas, and dew condensation has occurred on the inner surface of the translucent window (the surface on a accommodation space side) and blocked light to reduce the intensity of the light, thus causing the problem of reducing measurement accuracy; however, as the fixation frame for attaching the translucent window to the sample accommodation part, using a metallic one having high thermal conductivity allows heat transferred from the sample accommodation part to be efficiently transferred to the translucent window via the fixation frame, and this prevents the occurrence of a large temperature difference between the translucent window and the sample gas to make it difficult for dew condensation to occur on the inner surface of the translucent window (the surface on the accommodation space side), making it possible to keep the measurement accuracy high.

Also, coolant may be forcibly circulated in the cooling part. Further, the cooling part may be formed of a block body; inside the block body, a circulation path through which coolant circulates may be formed; and the coolant introduced into the circulation path from an introduction port of the circulation path may be led out of the circulation path from a lead-out port of the circulation path. Still further, insulation parts may be interposed between the sample accommodation part and both the light source part and the light receiving part; as with the respective insulation parts, cooling parts may be interposed between the sample accommodation part and both the light source part and the light receiving part; the coolant led out through a lead-out port from inside a circulation path of the cooling part disposed on a light receiving part side with respect to the sample accommodation part may be introduced through an introduction port into a circulation path of the cooling part disposed on a light source part side with respect to the sample accommodation part, so that in such a configuration, despite using the two cooling parts, it is sufficient to provide one by one the introduction port and the lead-out port to be connected to a device for forcibly circulating the coolant, such as a pump, facilitating connecting work, and since the coolant is circulated through the cooling part on the light source part side after the coolant has been circulated through the cooling part on the light receiving part side, the light receiving part having low heat resistance as compared with the light source part can be efficiently cooled at low temperature.

Also, a semiconductor manufacturing device using the absorbance meter according to the present invention is one that carries material gas produced by heating a material (e.g., heating to 300° C. or more) with the material gas mixed with carrier gas, and passes mixed gas, which results from mixing the material gas and the carrier gas, through the sample accommodation part of the absorbance meter as sample gas to perform measurement.

In such a configuration, even when using a low vapor pressure material as the source material of the material gas to be carried by the semiconductor manufacturing device, the mixed gas at high temperature can be accurately measured. In addition, conventional semiconductor manufacturing devices include one in which in each device such as a plasma generator disposed in a deposition chamber, a cooling part of a type adapted to circulate coolant is used, and when using the absorbance meter according to the present invention in such a semiconductor manufacturing device, the coolant can also be used for the absorbance meter.

In addition, in the above-described semiconductor manufacturing device, the material gas may be carried mixed with the carrier gas that is preheated. In this case, since the carrier gas to be mixed with the material gas is preheated, a reduction in the temperature of the material gas caused by the mixture of the carrier gas can be suppressed, and this enables the mixed gas at high temperature to be circulated through the absorbance meter.

Also, the semiconductor manufacturing device using the absorbance meter according to the present invention is one in which the sample gas is mixed gas in which diluent gas is further added to the material gas and the carrier gas.

In addition, in the above-described semiconductor manufacturing device, the material gas and the carrier gas may be added with the diluent gas that is preheated. In this case, since the diluent gas to be added to the material gas and the carrier gas is preheated, a reduction in the temperature of the material gas and the carrier gas caused by the mixture of the diluent gas can be suppressed, and this enables the mixed gas at high temperature to be circulated through the absorbance meter.

### Advantageous Effects of Invention

According to the present invention configured as described above, even when measuring high-temperature sample gas, the need for increasing the distance from a light source part to a light receiving part is eliminated, and this enables measurement accuracy to be kept high.

### BRIEF DESCRIPTION OF DRAWINGS

FIG. 1 is a schematic cross-sectional view schematically illustrating the configuration of an absorbance meter in an embodiment of the present invention.

FIG. 2 is a cross-sectional view illustrating a state where a cooling part according to the same embodiment is cut along a circumferential surface.

FIG. 3 is a schematic diagram illustrating a semiconductor manufacturing device using the absorbance meter according to the same embodiment.

FIG. 4 is a flowchart illustrating a procedure for operating the semiconductor manufacturing device using the absorbance meter according to the same embodiment.

FIG. 5 is a plan view illustrating an absorbance meter according to another embodiment.

FIG. 6 is a partial cross-sectional view illustrating a sample accommodation part according to another embodiment.

FIG. 7 is a partial cross-sectional view illustrating a sample accommodation part according to another embodiment.

FIG. 8 is a schematic diagram illustrating a semiconductor manufacturing device according to another embodiment.

### REFERENCE SIGNS LIST

100 Absorbance meter
10 Sample accommodation part
20 Light source part
30 Light receiving part
40a First insulation part
40b Second insulation part
50a First cooling part
50b Second cooling part
200, 300 Semiconductor manufacturing device
210 Tank
220 Carrier gas introduction path
221 Lead-out path
222 Diluent gas introduction path
230 Carrier gas flow rate regulation part
240 Carrier gas preheater
250 Diluent gas flow rate regulation part
260 Diluent gas preheater
270 Measurement part
280 Information processor
281 Flow rate control part
282 Control limit sensing part

### DESCRIPTION OF EMBODIMENTS

In the following, the absorbance meter according to the present invention will be described with reference to the drawings.

An absorbance meter 100 of the present embodiment is one using a so-called infrared spectroscopy (IR) that radiates infrared light having a predetermined wavelength to sample gas, and from the attenuation rate (transmittance) of it, measures the characteristics of a measurement target material contained in the sample gas. In addition, absorbance meters using the infrared spectroscopy include one using a Fourier transform infrared spectroscopy (FTIR) and one using a non-dispersive infrared analysis method (NDIR), and the present invention can also be applied to an absorbance meter using any of the infrared spectroscopies.

Also, the absorbance meter 100 of the present embodiment is used in a bubbling type semiconductor manufacturing device 200. Specifically, it is used when, in the bubbling type semiconductor manufacturing device 200, carrying material gas produced by vaporizing a low vapor pressure material together with carrier gas, and measuring a flow rate index value directly or indirectly indicating the flow rate of the material gas in mixed gas consisting of the material gas and the carrier gas or a flow rate index value directly or indirectly indicating the flow rate of the material gas in mixed gas produced by further adding diluent gas to the material gas and the carrier gas. In addition, in this case, each of the mixed gases serves as the sample gas.

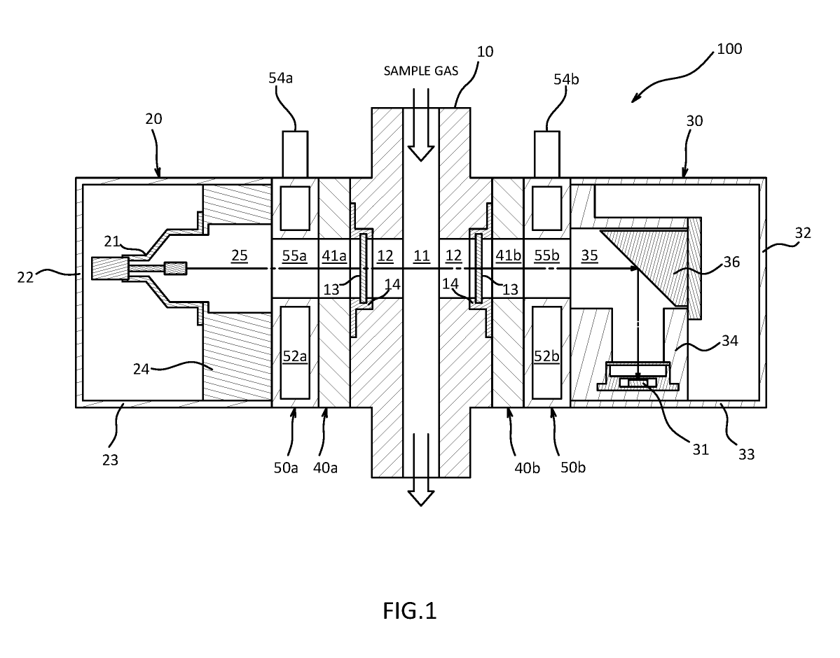

As illustrated in FIG. 1, the absorbance meter 100 according to the present embodiment includes: a sample accommodation part 10 including an accommodation space 11 for accommodating the sample gas; a light source part 20 for radiating the light into the accommodation space 11; a light receiving part 30 for receiving light exiting from inside the accommodation space 11; a first insulation part 40a that is interposed between the sample accommodation part 10 and the light source part 20 and disposed adjacent to the sample accommodation part 10; a second insulation part 40b that is interposed between the sample accommodation part 10 and the light receiving part 30 and disposed adjacent to the sample accommodation part 10; a first cooling part 50a that is interposed between the sample accommodation part 10 and the light source part 20 as with the first insulation part 40a and disposed adjacent to the first insulation part 40a and the light source part 20; and a second cooling part 50b that is interposed between the sample accommodation part 10 and the light receiving part 30 as with the second insulation part 40b and disposed adjacent to the second insulation part 40b and the light receiving part 30. Accordingly, the first insulation part 40a is arranged on the sample accommodation part 10 side with respect to the first cooling part 50a and the second insulation part 40b is arranged on the sample accommodation part 10 side with respect to the second cooling part 50b. In doing so, in the present embodiment, the insulation parts and the cooling parts are separately arranged, and the insulation parts are positioned on the sample accommodation part sides with respect to the cooling parts.

The sample accommodation part 10 is a flow type one formed in a cylindrical shape whose both ends are opened, and a hollow extending in the axial direction of the cylindrical body serves as the accommodation space 11 for accommodating the sample gas. In addition, the sample gas is adapted to be introduced from an opening at one end, pass through the accommodation space 11, and be led out of an opening at the other end. Accordingly, the sample gas is adapted to flow in the axial direction of the accommodation space 11. Further, in side wall parts opposite sandwiching the accommodation space 11 of the sample accommodation part 10, a pair of horizontal holes 12, 12 extending and penetrating in directions orthogonal to the axial direction of the accommodation space 11 (direction in which the sample gas flows) are formed. Each of the horizontal holes 12 has an inner wall of a stepped shape whose outer side is wide as compared with an inner side. Also, a translucent window 13 is attached via a fixation frame 14 in such a manner as to block each of the horizontal holes 12. The pair of translucent windows 13, 13 is adapted to enable the light radiated from outside the sample accommodation part 10 to pass therethrough while crossing the accommodation space 11 in a direction orthogonal to the axial direction. In addition, the sample accommodation part 10 is formed of a metal material, and adapted to be able to regulate the inside of the accommodation space 11 to a constant temperature by a heater (not illustrated) attached to the side wall. The translucent windows 13 are plate-shaped ones made of sapphire glass or the like and having translucency.

The fixation frames 14 are annularly formed, and fixed to the sample accommodation part 10, arranged at the openings on the outer sides of the horizontal holes 12 with the horizontal holes 12 and the hollow part communicated. Also, the translucent windows 13 are fixed fitted into grooves formed along the inner circumferences of the fixation frames 14 in such a manner as to block the hollows of the fixation frames 14. In addition, the fixation frames 14 are formed of a metal material. Accordingly, the present invention is configured to attach the translucent windows 13 via the metallic fixation frames 14 in such a manner as to block the horizontal holes 12 leading to the accommodation space 11 of the sample accommodation part 10.

The light source part 20 is structured to allow a light source holding structure 22 to hold a light source 21 for radiating the light. Also, the light source part 20 is attached to the sample accommodation part 10 via the first insulation part 40a and the first cooling part 50a. In addition, as the light source 21, for example, an incandescent type one adapted to emit light by heating a filament, an LED, or a laser device can be used.

The light source holding structure 22 is structured to fix the light source 21 into a case body 23 via an accompanying member. In addition, the accompanying member is a member for fixing the light source 21 into the case body 23, and for example, in the present embodiment, where the case body 23 is opened in a direction facing the sample accommodation part 10, represents a cover body 24 attached in such a manner as to block the opening. In the cover body 24, an insertion hole 25 is formed in a part facing the translucent window 13 on the one side of the sample accommodation part 10, and the light source 21 is fixed with a radiation direction facing the insertion hole 25. This allows the light radiated from the light source 21 to pass through the insertion hole 25 of the cover body 24 and travel toward the translucent window 13 on the one side.

The light receiving part 30 is structured to allow a light detector holding structure 32 to hold a light detector 31 for detecting light. Also, the light receiving part 30 is attached to the sample accommodation part 10 via the second insulation part 40b and the second cooling part 50b.

The light detector holding structure 32 is structured to fix the light detector 31 into a case body 33 via an accompanying member. In addition, the accompanying member is a member for fixing the light detector 31 into the case body 33, and for example, in the present embodiment, where the case body 33 is opened in a direction facing the sample accommodation part 10, represents a cover body 34 attached in such a manner as to block the opening. In the cover body 34, an insertion hole 35 extending inward from a part facing the translucent window 13 on the other side of the sample accommodation part 10 is formed, and at the end point of the insertion hole 35 on the deep side, the light detector 31 is fixed. In addition, the insertion hole 35 is of a shape that extends inward along a traveling direction of light exiting from the translucent window 13 on the other side of the sample accommodation part 10 and then bends at a right angle. Also, in the insertion hole 35, a reflective mirror 36 is disposed at a bending position, and the reflective mirror 36 bends the traveling direction of the light exiting from the translucent window 13 on the other side of the sample accommodation part 10 and guides the bent light so that the bent light reaches the light detector 31 disposed at the terminal on the deep side of the insertion hole 35. In addition, the reflective mirror 36 does not only bend the traveling direction of the light exiting from the translucent window 13 on the other side of the sample accommodation part 10 but plays a role in condensing the light onto the light detector 31. Further, although not illustrated, provided in the case body 33 is an information processor that, on the basis of the intensity of light detected by the light detector 31, calculates the characteristics of a measurement target material contained in the sample gas, such as concentration and partial pressure.

The first insulation part 40a and the second insulation part 40b are formed of an insulating material of a block shape, and formed of a material whose thermal-conductivity coefficient is lower than the material forming the sample accommodation part 10. Also, the first insulation part 40a has a role in blocking to some extent the heat of the sample gas transferred from the sample accommodation part 10 from being transferred to the light source part 20 side, and is attached in a state of being sandwiched between the sample accommodation part 10 and the first cooling part 50a with the inner surface adjacent to and in close contact with the surface of the sample accommodation part 10 on the light source part 20 side and the outer surface adjacent to and in close contact with the inner surface of the first cooling part 50a. Also, the second insulation part 40b has a role in blocking to some extent the heat of the sample gas transferred from the sample accommodation part 10 from being transferred to the light receiving part 30 side, and is attached in a state of being sandwiched between the sample accommodation part 10 and the second cooling part 50b with the inner surface adjacent to and in close contact with the surface of the sample accommodation part 10 on the light receiving part 30 side and the outer surface adjacent to and in close contact with the inner surface of the second cooling part 50b. In addition, in parts of the first insulation part 40a and second insulation part 40b facing the translucent windows 13, 13 of the sample accommodation part 10, through-holes 41a, 41b respectively penetrating from the inner surfaces to the outer surfaces are formed.

The first cooling part 50a and the second cooling part 50b are respectively formed of flat-shaped block bodies 51a, 51b superior in thermal conductivity. Also, the first cooling part 50a has a role in cooling the heat of the sample gas transferred from the sample accommodation part 10, which cannot be completely blocked by the first insulation part 40a, to prevent the light source part 20 from being heated, and is attached in a state of being sandwiched between the light source part 20 and the first insulation part 40a with the inner surface of the block body 51a adjacent to and in close contact with the outer surface of the first insulation part 40a and the outer surface of the block body 51a adjacent to and in close contact with the inner surface of the light source part 20. In addition, the first cooling part 50a performs cooling so that at least the surface opposite to the light source part 20 is kept at temperature equal to or lower than the temperature of the light source part 20. Also, the second cooling part 50b has a role in cooling the heat of the sample gas transferred from the sample accommodation part 10, which cannot be completely blocked by the second insulation part 40b, to prevent the light receiving part 30 from being heated, and is attached in a state of being sandwiched between the light receiving part 30 and the second insulation part 40b with the inner surface of the block body 51b adjacent to and in close contact with the outer surface of the second insulation part 40b and the outer surface of the block body 51b adjacent to and in close contact with the inner surface of the light receiving part 30. In addition, the second cooling part 50b performs cooling so that at least the surface opposite to the light receiving part 30 is kept at temperature equal to or lower than the temperature of the light receiving part 30.

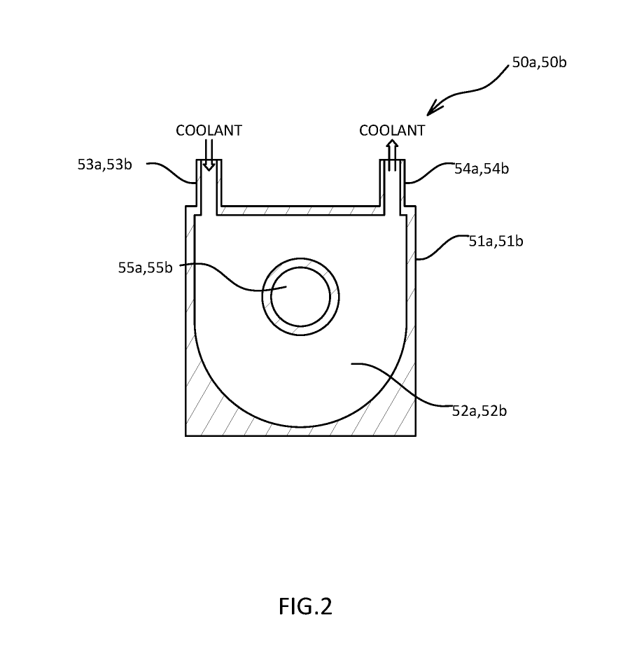

Inside the block bodies 51a, 51b of the first cooling part 50a and second cooling part 50b, as illustrated in FIG. 2, circulation paths 52a, 52b through which coolant flows are formed, and the circulation paths 52a, 52b have pairs of openings, in which one openings of the circulation paths 52a, 52b form introduction ports 53a, 53b for introducing the coolant into the circulation paths 52a, 52b, and the other openings of the circulation paths 52a, 52b form lead-out ports 54a, 54b for leading the coolant out of the circulation paths 52a, 52b. In addition, in parts of the block bodies 51a, 51b facing the translucent windows 13, 13 of the sample accommodation part 10, through-holes 55a, 55b penetrating from the inner surfaces to the outer surfaces are formed. Also, the circulation paths 52a, 52b formed inside the block bodies 51a, 51b are formed in such a manner as to surround the through-holes 55a, 55b. In doing so, the coolant introduced into the circulation paths 52a, 52b from outside the circulation paths 52a, 52b through the introduction ports 53a, 53b circulates along the through-holes 55a, 55b, and is led out of the circulation paths 52a, 52b from inside the circulation paths 52a, 52b through the lead-out ports 54a, 54b. In addition, the coolant may be a liquid one or a gaseous one as long as it flows in the circulation paths 52a, 52b; however, considering safety, costs, and a heat transfer coefficient, it is preferable to use water. Further, although not illustrated, the lead-out port 54a of the first cooling part 50a and the introduction port 53b of the second cooling part 50b are connected to a pump for forcibly circulating the coolant, and the lead-out port 54b of the second cooling part 50b is connected to the introduction port 53a of the first cooling part 50a.

In addition, the through-hole 55a of the first cooling part 50a communicates with the through-hole 41a formed in the first insulation part 40a, as well as communicates with the insertion hole 25 formed in the light source part 20, and in doing so, one communication hole extending from the light source 21 of the light source part 20 to the translucent window 13 on the one side of the sample accommodation part 10 is formed and serves as a path for the light radiated from the light source 21. Also, the through-hole 55b of the second cooling part 50b communicates with the through-hole 41b formed in the second insulation part 40b, as well as communicates with the insertion hole 35 formed in the light receiving part 30, and in doing so, one communication hole extending from the light detection part 31 of the light receiving part 30 to the translucent window 13 on the other side of the sample accommodation part 10 is formed and this communication hole serves as a path for the light radiated from the light source 21.

To describe the operation of the absorbance meter of the present embodiment, first, the light radiated from the light source of the light source part 20 gets out of the light source holding structure 22 through the insertion hole 25, passes through the through-holes 55a, 41a of the first cooling part 50a and the first insulation part 40a, and reaches the sample accommodation part 10. Subsequently, the light having reached the sample accommodation part 10 is incident into the accommodation space 11 from the translucent window 13 on the one side, passes through the sample gas flowing through the accommodation space 11, and exits outside the accommodation space 11 from the translucent window 13 on the other side in a state of being attenuated. Then, the light having exited from the translucent window 13 on the other side passes through the through-holes 41b, 55b of the second insulation part 40b and second cooling part 50b, and reaches the light receiving part 30. Finally, the light having reached the light receiving part 30 is incident into the insertion hole 35, bent by the reflective mirror 36, and guided to the light detector 31. Then, on the basis of the intensity of the light detected by the light detector 31, the information processor calculates the characteristics of the measurement target material contained in the sample gas, such as concentration and partial pressure. Also, during the operation, the coolant having flowed out from the pump is introduced into the circulation path 52b through the introduction port 53b of the second cooling part 50b for cooling the light receiving part 30, led out of the circulation path 52b through the lead-out port 54b after circulating through the circulation path 52b along the through-hole 55b, subsequently introduced into the circulation path 52a through the introduction port 53a of the first cooling part 50a for cooling the light source part 20, led out of the circulation path 52a through the lead-out port 54a after circulating through the circulation path 52a along the through-hole 55a, and returns to the pump for circulation.

Next, the semiconductor manufacturing device 200 using the absorbance meter 100 of the present embodiment, specifically, one embodiment of the bubbling type semiconductor manufacturing device 200 will be described on the basis of drawings.

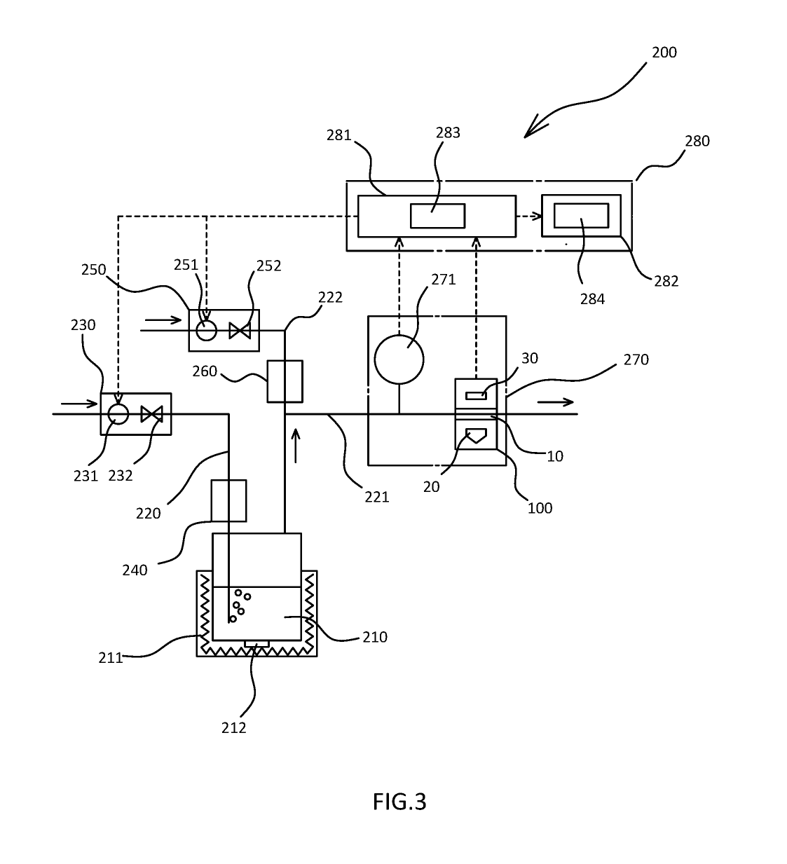

As illustrated in FIG. 3, the semiconductor manufacturing device 200 of the present embodiment has: a tank 210 for accommodating a material; a carrier gas introduction path 220 for introducing carrier gas into a liquid phase space of the tank 210; a lead-out path 221 for leading material gas and the carrier gas out of a gas phase space of the tank 210; a diluent gas introduction path 222 for introducing diluent gas into the lead-out path 221; a gas flow rate regulation part 230 and carrier gas preheater 240 disposed in the carrier gas introduction path 220; a diluent gas flow rate regulation part 250 and diluent gas preheater 260 disposed in the diluent gas introduction path 222; a measurement part 270 disposed in the lead-out path 221; and an information processor 280 including a flow rate control part 281 and a control limit sensing part 282, and as one of measurement devices constituting the measurement part 270, the absorbance meter 100 of the present embodiment is used. In addition, although not illustrated, the start point of the carrier gas introduction path 220 is connected to a carrier gas supply mechanism; the start point of the diluent gas introduction path 222 is connected to a diluent gas supply mechanism; and the end point of the lead-out path 221 is connected to a deposition chamber into which mixed gas is supplied, whereby a deposition device is constituted.

The tank 210 is adapted to be able to heat the accommodated material by a heater 211, and adapted to monitor the temperature inside the tank 210 by a thermometer 212 to keep the temperature inside the tank 210 at a predetermined set temperature.

The carrier gas flow rate regulation part 230 is one for regulating the flow rate of the carrier gas to be introduced into the tank 210, and a so-called MFC (mass flow controller). The carrier gas flow rate regulation part 230 roughly includes: a flowmeter 231 for measuring the flow rate of the carrier gas flowing through the carrier gas introduction path 220; and a valve 232 that is disposed on the downstream side of the flowmeter 231 in the carrier gas introduction path 220 and for adjusting an opening level to regulate the flow rate of the carrier gas to be introduced into the tank 210, compares a set flow rate transmitted from the flow rate control part 281 and a measured flow rate measured by the flowmeter 231 to adjust the opening/closing of the valve 232 so that both of the flow rates coincide, and performs regulation so that the carrier gas having the set flow rate transmitted from the flow rate control part 281 flows through the carrier gas introduction path 220.

The carrier gas preheater 240 is disposed on the downstream side of the carrier gas flow rate regulation part 230 in the carrier gas introduction path 220, is one for preheating the carrier gas to be introduced into the tank 210 just before the introduction into the tank 210, and has a role in suppressing a reduction in the temperature inside the tank 210 caused by the introduction of the carrier gas.

The diluent gas flow rate regulation part 250 is one for regulating the flow rate of the diluent gas to be introduced into the lead-out path 221, and a so-called MFC (mass flow controller). The diluent gas flow rate regulation part 250 roughly includes: a flowmeter 251 for measuring the flow rate of the diluent gas flowing through the diluent gas introduction path 222; and a valve 252 that is disposed on the downstream side of the flowmeter 251 in the diluent gas introduction path 222 and for adjusting an opening level to regulate the flow rate of the carrier gas to merge into the lead-out path 221, compares a set flow rate transmitted from the flow rate control part 281 and a measured flow rate measured by the flowmeter 251 to adjust the opening/closing of the valve 252 so that both of the flow rates coincide, and performs regulation so that the diluent gas having the set flow rate transmitted from the flow rate control part 281 flows through the diluent gas introduction path 222.

The diluent gas preheater 260 is disposed on the downstream side of the diluent gas flow rate regulation part 250, is one for preheating the diluent gas to be introduced into the tank 210 just before the introduction into the tank 210, and has a role in suppressing a reduction in the temperature inside the tank 210 caused by the introduction of the diluent gas.

The measurement part 270 is constituted by a pressure sensor 271 and the absorbance meter 100 of the present embodiment, and both are disposed on the downstream side of a position of the lead-out path 221 where the diluent gas introduction path 222 is connected. Also, the pressure sensor 271 measures the pressure (total pressure) of the mixed gas flowing through the lead-out path 221, and the absorbance meter 100 of the present embodiment measures the partial pressure (flow rate index value) of the material gas in the mixed gas flowing through the lead-out path 221. In addition, the absorbance meter 100 of the present embodiment is such that an opening on one end side of the sample accommodation part 10 is connected to the upstream side of the lead-out path 221 and an opening on the other side of the sample accommodation part 10 is connected to the downstream side of the lead-out path 221, and this allows the mixed gas flowing through the lead-out path 221 to pass along the axial direction of the accommodation space 11 of the sample accommodation part 10.

The information processor 280 is a general-purpose or dedicated computer, stores a predetermined program in a memory, cooperatively operates a CPU and its peripheral devices in accordance with the program, and thereby fulfills functions as the flow rate control part 281 and the control limit sensing part 282. The flow rate control part 281 is one that refers to the partial pressure of the material gas in the mixed gas acquired from the absorbance meter 100, transmits a required set flow rate to both of the flow rate regulation parts 230, 250 so that the flow rate of the material gas in the mixed gas comes close to a target flow rate, and controls the flow rates of the carrier gas and diluent gas. In addition, the flow rate control part 281 is provided with an input part 283 enabling various pieces of information to be inputted, such as a touch panel. Also, the control limit sensing part 282 is connected to the flow rate control part 281, and fulfills a function of, on the basis of various pieces of information acquired from the flow rate control part 281, sensing the occurrence of a control limit situation that is a situation where flow rate control of the material gas in the mixed gas cannot be ensured with predetermined performance depending on flow rate regulation of the carrier gas by the flow rate control part 281 and outputting this. In addition, the control limit sensing part 282 is provided with a display part 284 capable of displaying various pieces of information.

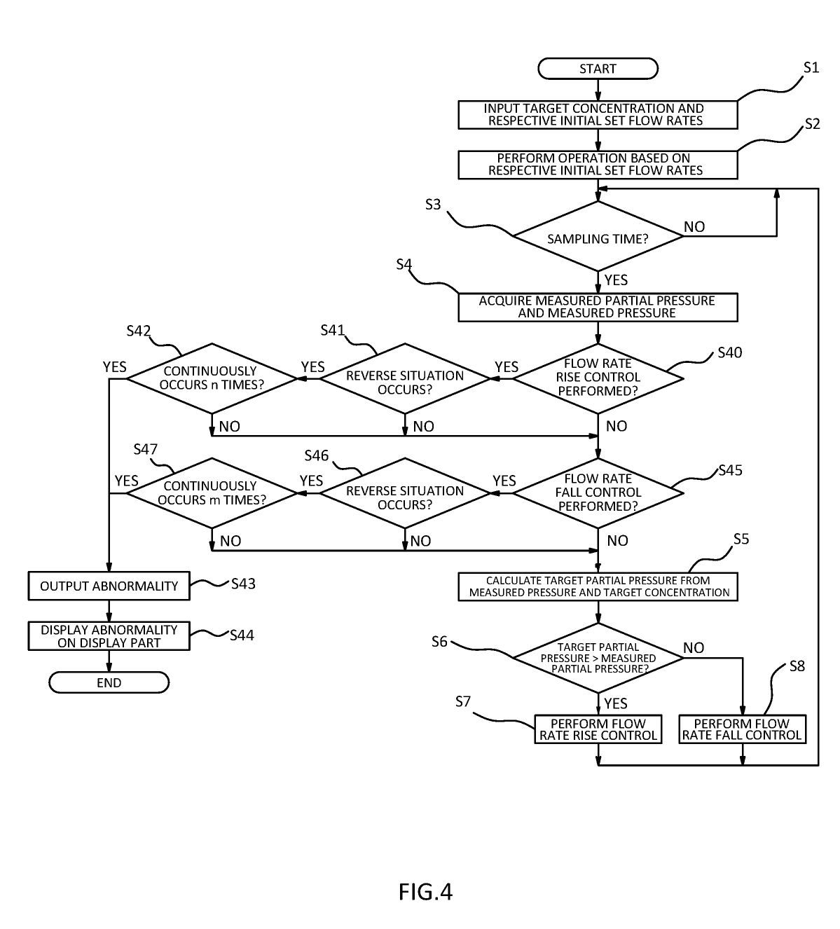

Next, an operational procedure for the semiconductor manufacturing device of the present embodiment will be described on the basis of a flowchart illustrated in FIG. 4.

First, using the input part 283, the target concentration of the material gas in the mixed gas optimum for a deposition process, and the initial set flow rates of the carrier gas and diluent gas are respectively inputted to the flow rate control part 281 (Step S1).

Then, the flow rate control part 281 transmits the initial set flow rate of the carrier gas to the carrier gas flow rate regulation part 230, as well as transmits the initial set flow rate of the diluent gas to the diluent gas flow rate regulation part 250. This allows the carrier gas flow rate regulation part 230 to regulate the flow rate of the carrier gas flowing through the carrier gas introduction path 220 to the initial set flow rate, as well as allows the diluent gas flow rate regulation part 250 to regulate the flow rate of the diluent gas flowing through the diluent gas introduction path 222 to the initial set flow rate, and as a result, the respective gases start circulating in the semiconductor manufacturing device 200 (Step S2).

Subsequently, when the mixed gas passes through the pressure sensor 271 and the absorbance meter 100 of the present embodiment, with a constant period (Step S3), the pressure sensor 271 measures the pressure of the mixed gas flowing through the lead-out path 221, and also the absorbance meter 100 measures the partial pressure of the material gas in the mixed gas flowing through the lead-out path 221 (Step S4).

After that, the flow rate control part 281 receives the measured pressure measured by the pressure sensor 271 and the measured partial pressure (measured flow rate index value) measured by the absorbance meter 100, and using the measured pressure and the target concentration, calculates the target partial pressure (target flow rate index value) of the material gas in the mixed gas required when assuming that the material gas in the mixed gas flowing through the lead-out path 221 has the target concentration, in accordance with Expression (1) (Step S5).

P vapor set=C×P total (1)

Here, P vapor set represents the target partial pressure of the material gas in the mixed gas, C the target concentration of the material gas in the mixed gas, and P total the pressure of the mixed gas.

Then, the flow rate control part 281 receives the measured partial pressure measured by the absorbance meter 100 to compare the measured partial pressure and the target partial pressure (Step S6), and when the measured partial pressure is smaller than the target partial pressure, transmits a set flow rate for increasing the flow rate of the carrier gas flowing through the carrier gas introduction path 220 to the carrier gas flow rate regulation part 230, as well as transmits a set flow rate for decreasing the flow rate of the diluent gas flowing through the diluent gas introduction path 222 to the diluent gas flow rate regulation part 250. In doing so, in order that the flow rate of the material gas in the mixed gas flowing through the lead-out path 221 comes close to the optimum flow rate, flow rate rise control in which the carrier gas flow rate regulation part 230 regulates the flow rate of the carrier gas flowing through the carrier gas introduction path 220 to the set flow rate, and also the diluent gas flow rate regulation part 250 regulates the flow rate of the diluent gas flowing through the diluent gas introduction path 222 to the set flow rate is performed (Step S7). On the other hand, when the measured partial pressure is larger than the target partial pressure, a set flow rate for decreasing the flow rate of the carrier gas flowing through the carrier gas introduction path 220 is transmitted to the carrier gas flow rate regulation part 230, and also a set flow rate for increasing the flow rate of the diluent gas flowing through the diluent gas introduction path 222 is transmitted to the diluent gas flow rate regulation part 250. In doing so, in order that the flow rate of the material gas in the mixed gas flowing through the lead-out path 221 comes close to the optimum flow rate, flow rate fall control in which the carrier gas flow rate regulation part 230 regulates the flow rate of the carrier gas flowing through the carrier gas introduction path 220 to the set flow rate, and also the diluent gas flow rate regulation part 250 regulates the flow rate of the diluent gas flowing through the diluent gas introduction path 222 to the set flow rate is performed (Step S8).

Also, the control limit sensing part 282 performs the following operation between Step S4 and Step S5. To describe in detail, first, it is determined whether or not the flow rate rise control was performed during the previous period (Step 40), when it is determined that the flow rate rise control was performed during the previous period, a measured partial pressure during the previous period measured by the absorbance meter 100 just before performing the flow rate rise control and a measured partial pressure during the present period measured by the absorbance meter 100 just after performing the flow rate rise control are compared to determine whether or not a reverse situation where the measured partial pressure during the present period supposed to be larger than the measured partial pressure during the previous period by the flow rate rise control is smaller than the measured partial pressure during the previous period occurs (Step S41), when it is determined that the reverse situation occurs, it is determined whether or not the reverse situation continuously occurs n times (Step S42), and when it continuously occurs n times, it is determined that the control limit situation occurs and this is outputted (Step S43) to display a warning on the display part 284 (Step S44). On the other hand, when it is determined in Step S40 that the flow rate rise control was not performed during the previous period, it is determined whether or not the flow rate fall control was performed during the previous period (Step S45), when it is determined that the flow rate fall control was performed during the previous period, a measured partial pressure during the previous period measured by the absorbance meter 100 just before performing the flow rate fall control and a measured partial pressure during the present period measured by the absorbance meter 100 just after performing the flow rate fall control are compared to determine whether or not a reverse situation where the measured partial pressure during the present period supposed to be smaller than the measured partial pressure during the previous period by the flow rate fall control is larger than the measured partial pressure during the previous period occurs (Step S46), when it is determined that the reverse situation occurs, it is determined whether or not the reverse situation continuously occurs m times (Step S47), and when it continuously occurs m times, it is determined that the control limit situation occurs and this is outputted (Step S43) to display a warning on the display part 284 (Step S44).

In addition, after displaying the warning on the display part 284 in Step S44, a gas control system may be automatically stopped so as to prevent the same situation from continuing any more, or a worker having confirmed the warning displayed on the display part 284 may manually stop the gas control system. Also, in place of or in addition to the operation between Step S4 and Step S5, the operation of, even when increasing the flow rate of the carrier gas, when the measured partial pressure after a predetermined period of time (e.g., after x periods, where x represents a predetermined integer) is increased only to a smaller value (e.g., a value of ½ or less, ⅓ or less, ¼ or less, or the like of a value supposed to be obtained) than the value supposed to be obtained if the measured partial pressure is increased substantially in proportion to an increase in the flow rate of the carrier gas, determining that the control limit situation occurs, or alternatively even when decreasing the flow rate of the carrier gas, when the measured partial pressure after a predetermined period of time (e.g., after y periods, where y represents a predetermined integer) is decreased only to a larger value (e.g., a value of ½ or more, ⅓ or more, ¼ or more, or the like of a value supposed to be obtained) than the value supposed to be obtained if the measured partial pressure is decreased substantially in proportion to a decrease in the flow rate of the carrier gas, determining that the control limit situation occurs may be performed.

In addition, in Step S1, the target total flow rate of the mixed gas optimum for the deposition process may be inputted to the flow rate control part 281 using the input part 283, and in the flow rate control in Step S7 and Step S8, when increasing/decreasing the flow rates of the carrier gas and diluent gas, the set flow rates of the carrier gas and diluent gas may be determined so that the flow rate of the mixed gas comes close to the target total flow rate.

Specifically, the flow rate control part 281 receives the measured pressure measured by the pressure sensor 271 and the measured partial pressure measured by the absorbance meter 100, as well as receives the set flow rate of the carrier gas set by the carrier gas flow rate regulation part 230 and the set flow rate of the diluent gas set by the diluent gas flow rate regulation part 250 at the time when these measured values were measured, and in the flow rate control in Step S7 and Step S8, using the measured pressure, the measured partial pressure, the set flow rate of the carrier gas, and the set flow rate of the diluent gas, the calculated total flow rate of the mixed gas is calculated in accordance with Expression (2) to determine the set flow rates of the carrier gas and diluent gas so that the calculated total flow rate of the mixed gas becomes equal to the predetermined target total flow rate of the mixed gas.

Q total=(Qc+Qd)/(1−P vapor ir/P total) (2)

Here, Q total represents the calculated total flow rate of the mixed gas, Qc the set flow rate of the carrier gas, Qd the set flow rate of the diluent gas, P vapor it the measured partial pressure of the material gas in the mixed gas, and P total the pressure (total pressure) of the mixed gas.

In the present embodiment, when performing the flow rate control, the flow rate of the carrier gas and the flow rate of the diluent gas are both increased/decreased; however, only any one of the flow rates can also be increased/decreased to perform the flow rate control. Also, in the present embodiment, it is determined every constant period whether or not each of the reverse situations occurs, and when any of the situations continues n, m times (n, m periods), it is determined that the control limit situation occurs and this is outputted; however, it may be monitored whether or not each of the reverse situations occurs, and when any of the situations continues for t hours, it may be determined that the control limit situation occurs and this may be outputted.

### Other Embodiments

The absorbance meter according to the present invention is not limited to the absorbance meter 100 of the above-described embodiment. For example, in the absorbance meter 100 of the above-described embodiment, on both of the light source part 20 side and light receiving part 30 side of the sample accommodation part 10, the insulation parts and the cooling parts are respectively disposed; however, any configuration is also possible as long as the configuration is one adapted to dispose an insulation part or insulation parts on any one of or both of the light source part 20 side and light receiving part 30 side of the sample accommodation part 10, and dispose a cooling part to be paired with at least one insulation part.

Specifically, a configuration adapted to dispose the first insulation part 40a and the first cooling part 50a on the light source part 20 side of the sample accommodation part 10 and not to dispose the second insulation part 40b and the second cooling part 50b on the light receiving part 30 side, a configuration adapted not to dispose the first insulation part 40a and the first cooling part 50a on the light source part 20 side of the sample accommodation part 10 and to dispose the second insulation part 40b and the second cooling part 50b on the light receiving part 30 side, a configuration adapted to dispose the first insulation part 40a and the first cooling part 50a on the light source part 20 side of the sample accommodation part 10 and to dispose only the second insulation part 40b on the light receiving part 30 side, and a configuration adapted to dispose only the first insulation part 40a on the light source part 20 side of the sample accommodation part 10 and to dispose the second insulation part 40b and the second cooling part 50b on the light receiving part 30 side are also possible, and these configurations are also included in the absorbance meter according to the present invention. These configurations are applied to the case where any one of the light source part 20 and the light receiving part 30 has thermal tolerance, and any of the configurations adapted to omit any one or both of the insulation part and the cooling part for a part having the thermal tolerance is applied. In addition, in the case where the insulation parts 40a, 40b are disposed on both of the light source part 20 side and light receiving part 30 side of the sample accommodation part 10, both of the insulation parts 40a, 40b may be integrally connected, and in the case where the cooling parts 50a, 50b are disposed on both of the light source part 20 side and light receiving part 30 side of the sample accommodation part 10, both of the cooling parts 50a, 50b may be integrally connected. Also, in the absorbance meter of the above-described embodiment, the insulation parts 40a, 40b and the cooling parts 50a, 50b are respectively linearly arranged side by side with respect to the sample accommodation part 10; however, as illustrated in FIG. 5, the insulation parts 40a, 40b and the cooling parts 50a, 50b may be arranged side by side while bending with respect to the sample accommodation part 10. In this case, the communication holes serving as light paths also bend, and therefore reflective mirrors have to be attached in the communication holes so that light travels along the communication holes.

Also, in the absorbance meter 100 according to the above-described embodiment, the light source part 20, first cooling part 50a, first insulation part 40a, sample accommodation part 10 are arranged mutually adjacently in this order, and the light receiving part 30, second cooling part 50b, second insulation part 40b, and sample accommodation part 10 are arranged mutually adjacently in this order; however, it is not necessarily required to be adjacent, and for example, between the sample accommodation part 10 and the first insulation part 40a, between the first insulation part 40a and the first cooling part 50a, between the first cooling part 50a and the light source part 20, between the sample accommodation part 10 and the second insulation part 40b, between the second insulation part 40b and the second cooling part 50b, or between the second cooling part 50b and the light receiving part 30, a gap or another member can also be interposed.

Also, as in the absorbance meter 100 according to the above-described embodiment, it is preferable to form the through-holes on the light path for the light emitted from the light source part 20 in the first insulation part 40a, second insulation part 40b, first cooling part 50a, and second cooling part 50b; however, on the light path for the light, members having translucency may be disposed, such as glass.

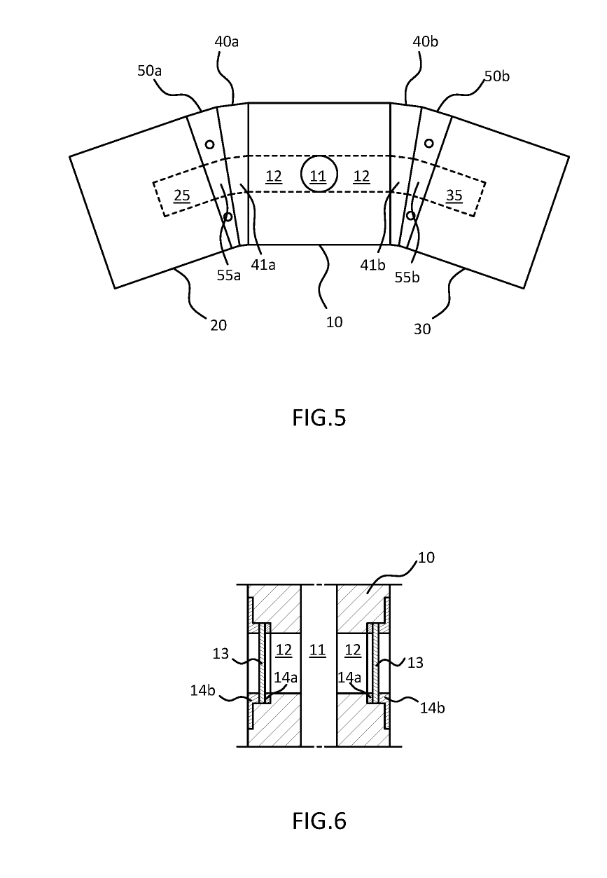

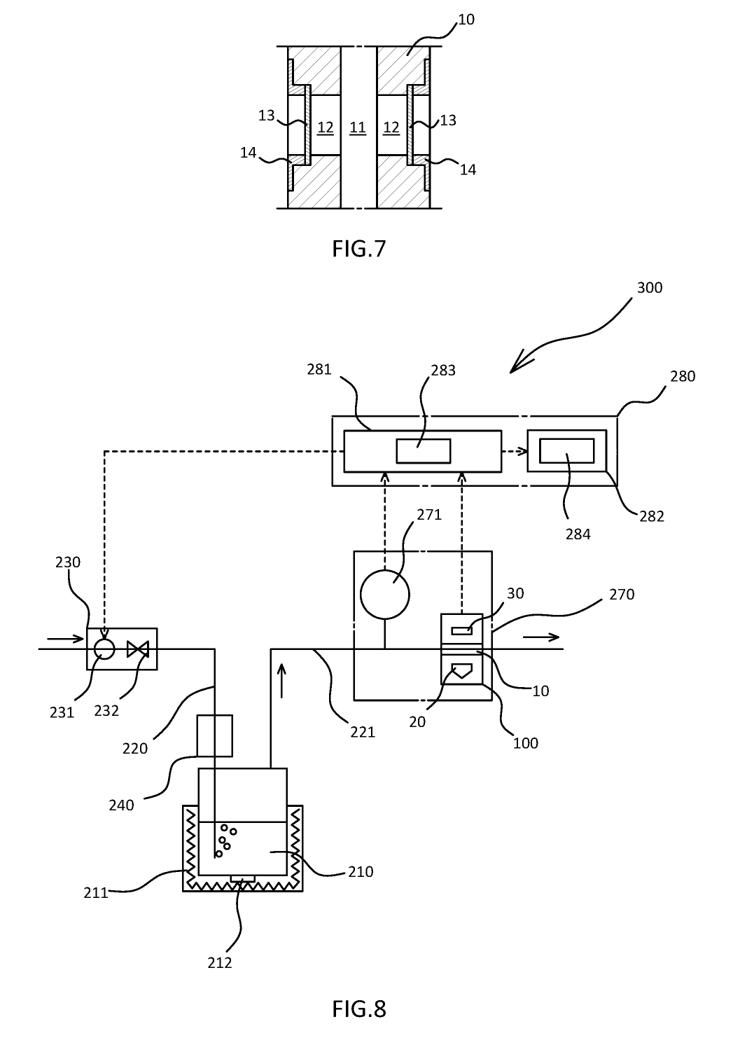

A method for fixing the translucent windows 13 to the sample accommodation part 10 according to the present invention is not limited to one in the above-described embodiment. For example, as illustrated in FIG. 6, the translucent windows 13 may be fixed in such a manner as to be sandwiched by annular-shaped first fixation frames 14a disposed on the steps formed on the circumferential walls of the horizontal holes 12 and annular-shaped second fixation frames 14b fixed in the openings of the horizontal holes 12. In this case, the fixation frames 14 for fixing the translucent windows 13 to the sample accommodation part 10 consist of two members. Further, as illustrated in FIG. 7, the translucent windows 13 may be disposed on the steps formed on the circumferential walls of the horizontal holes 12, and the translucent windows 13 may be fixed by annular-shaped fixation frames 14 fixed in the openings of the horizontal holes 12 in such a manner as to be pressed against the steps.

In the case where the two cooling parts are used as in the above-described embodiment, two three-way connecting pipes may be used, and by connecting two openings of one of the connecting pipes to the introduction ports of both the cooling parts, as well as connecting the remaining one opening to the pump, and connecting two openings of the other connecting pipe to the lead-out ports of both the cooling parts, as well as connecting the remaining one opening to the pump, the pump and both the cooling parts may be connected. In this case, since the coolant led out from the pump is divided into two portions and introduced into both the cooling parts, both the cooling parts can be equally cooled. Also, even in this case, by attaching the two connecting pipes to both the cooling parts in advance, work for connecting to the pump can be simplified as in the absorbance meter 100 of the above-described embodiment.

Further, as the cooling part in each of the above-described embodiments, one adapted to forcibly perform cooling by reducing the temperature of the cooling part itself, such as one adapted to perform cooling by circulating the coolant by a pump, a fan, or the like as in each of the above-described embodiments, or one adapted to perform cooling using a reduction in the temperature of itself, such as a lower temperature side of a Peltier element or one adapted to perform cooing by improving the heat dissipation efficiency of the cooling part itself, such as one adapted to perform cooling by facilitating heat dissipation through multiple heat dissipation fins, such as a heat sink can be employed, and further one in which these are combined can also be employed. Also, as an insulation material used for the insulation part in each of the above-described embodiments, a thermoplastic resin such as polyphenylene sulfide (PPS) or polyetheretherketone (PEEK), an inorganic laminated plate using ceramic or glass fiber as a base material, or the like can be used.

Also, the semiconductor manufacturing device using the absorbance meter 100 according to the present invention is not limited to the semiconductor manufacturing device 200 of the above-described embodiment. For example, as in a semiconductor manufacturing device 300 illustrated in FIG. 8, it may be adapted to eliminate the diluent gas introduction path 222 included in the semiconductor manufacturing device 200 of the above-described embodiment, and carry material gas produced by, in the tank 210, vaporizing the material only by the carrier gas introduced into the tank 210 through the carrier gas introduction path 220. In addition, except for eliminating the diluent gas introduction path 222, the diluent gas flow rate regulation part 250 and diluent gas preheater 260 disposed in the diluent gas introduction path 222 from the semiconductor manufacturing device 200 of the above-described embodiment, the semiconductor manufacturing device 300 has the same configuration as that of the semiconductor manufacturing device 200. Accordingly, the measurement target of the measurement part 270 is mixed gas consisting of the carrier gas and material gas led out of the tank 210 through the lead-out path 221.

In the semiconductor manufacturing device according to the present invention, it is only necessary that the measurement part is adapted to be able to measure at least one of flow rate index values that are values directly or indirectly indicating the concentration of the material gas in the mixed gas, and the measurement part may also be adapted to be able to measure another value related to the mixed gas. In addition, the semiconductor manufacturing device 200 of the above-described embodiment is adapted to be able to measure the pressure of the mixed gas in addition to the partial pressure of the material gas in the mixed gas as the flow rate index value.

In the semiconductor manufacturing device 200 of the above-described embodiment, as the flow rate index value, the partial pressure of the material gas in the mixed gas is used; however, the flow rate index value is not particularly limited as long as it is a value directly or indirectly indicating the concentration of the material gas in the mixed gas. Also, in the semiconductor manufacturing device 200 of the above-described embodiment, the flow rate index value is measured with the constant period to perform the flow rate control; however, a concentration index value may be continuously measured to perform concentration control.

In each of the above-described embodiments, as the carrier gas flow rate regulation part 230 and the diluent gas flow rate regulation part 250, ones in which the valves 232, 252 are disposed on the downstream sides of the flowmeters 231, 251 are used; however, ones in which the valves 232, 252 are disposed on the upstream sides of the flowmeters 231, 251 may be used.

### INDUSTRIAL APPLICABILITY

Obtained is an absorbance meter capable of, when measuring high-temperature sample gas, without increasing the distance from a light source part to a light receiving part, protecting the light source part and the light receiving part from the heat of the sample gas and keeping measurement accuracy high.

1. An absorbance meter comprising:
a sample accommodation part provided with a pair of translucent windows oppositely attached sandwiching an accommodation space for accommodating sample gas;
a light source part for radiating light into the accommodation space through a translucent window on one side; and
a light receiving part for receiving light passing through the accommodation space and exiting from a translucent window on the other side, the absorbance meter further comprising:
an insulation part interposed between the sample accommodation part and any one or both of the light source part and the light receiving part; and
a cooling part interposed between the sample accommodation part and the light source part or the light receiving part, as with the at least one insulation part, wherein
the insulation part is arranged on a sample accommodation part side with respect to the cooling part.

2. The absorbance meter according to claim 1, wherein
coolant is forcibly circulated in the cooling part.

3. The absorbance meter according to claim 1, wherein
at least one set of parts that are selected from the sample accommodation part, the light source part, the light receiving part, the insulation part interposed between the sample accommodation part and the light source part, the cooling part interposed between the sample accommodation part and the light source part as with the insulation part, the insulation part interposed between the sample accommodation part and the light receiving part, and the cooling part interposed between the sample accommodation part and the light receiving part as with the insulation part and mutually oppositely arranged is such that the parts are adjacent with opposite surfaces thereof in close contact.

4. The absorbance meter according to claim 1, wherein:
the cooling part is formed of a block body; inside the block body, a circulation path through which coolant circulates is formed; and the coolant introduced into the circulation path from an introduction port of the circulation path is led out of the circulation path from a lead-out port of the circulation path.

5. The absorbance meter according to claim 4, wherein:
insulation parts are interposed between the sample accommodation part and both the light source part and the light receiving part; as with the respective insulation parts, cooling parts are interposed between the sample accommodation part and both the light source part and the light receiving part; the coolant led out through a lead-out port from inside a circulation path of the cooling part disposed on a light receiving part side with respect to the sample accommodation part is introduced through an introduction port into a circulation path of the cooling part disposed on a light source part side with respect to the sample accommodation part.

6. The absorbance meter according to claim 1, wherein
at least one of the translucent windows is attached to the sample accommodation part via a fixation frame, and the fixation frame is formed of a metal material.

7. A semiconductor manufacturing device that carries material gas produced by heating a material with the material gas mixed with carrier gas, and passes mixed gas through the sample accommodation part of the absorbance meter according to claim 1 as sample gas to perform measurement, the mixed gas resulting from mixing the material gas and the carrier gas.

8. The semiconductor manufacturing device according to claim 7, wherein
the material gas is carried mixed with the carrier gas that is preheated.

9. The semiconductor manufacturing device according to claim 7, wherein
the sample gas is mixed gas in which preheated diluent gas is further added to the material gas and the carrier gas.
